(19) United States
(12) Patent Application Publication
(10) Pub. No.: US 2011/0220182 A1
(43) Pub. Date: Sep. 15, 2011

(54) Solar Panel Tracking and Performance Monitoring Through Wireless Communication

(75) Inventors: Chang-Ming Lin, San Jose, CA (US); Yu-Chih Chen, Danville, CA (US)

(73) Assignee: RFMARQ, INC., Monte Sereno, CA (US)

(21) Appl. No.: 12/896,687

(22) Filed: Oct. 1, 2010

Related U.S. Application Data
(60) Provisional application No. 61/313,686, filed on Mar. 12, 2010.
(60) Provisional application No. 61/330,210, filed on Apr. 30, 2010.
(60) Provisional application No. 61/384,294, filed on Sep. 19, 2010.

(51) Int. Cl. H01L 31/048

(52) U.S. Cl. 136/251

(57) ABSTRACT

In one embodiment, a wireless device is embedded in a solar panel for providing remote tracking and/or performance monitoring of the solar panel. The wireless device may be a wireless tracking device including a memory for storing the identification or identity information of the solar panel or of the individual solar cells forming the panel. The wireless device may be a wireless tracking and monitoring device to provide both tracking and performance monitoring functions. In another embodiment, the wireless device is affixed to the exposed side of the back sheet of the solar panel but within the junction box interface so that the wireless device is enclosed in the junction box housing. In other embodiments, some of the elements of the wireless device may be embedded in the solar panel while other elements are affixed to the exposed back sheet inside the junction box housing.

### CROSS-REFERENCE TO RELATED APPLICATIONS

This application claims the benefit of U.S. Provisional Patent Application Ser. No. 61/313,686, filed on Mar. 12, 2010, U.S. Provisional Patent Application Ser. No. 61/330,210, filed on Apr. 30, 2010, and U.S. Provisional Patent Application Ser. No. 61/384,294, filed on Sep. 19, 2010, which applications are incorporated herein by reference in their entireties.

### FIELD OF THE INVENTION

The invention relates to solar panel tracking and performance monitoring and more particularly, a solar panel incorporated with a wireless tracking and monitoring device to enable wireless tracking and monitoring of the solar panel.

### DESCRIPTION OF THE RELATED ART

A solar panel, also referred to as a photovoltaic panel, a solar module, or a photovoltaic module, is a packaged interconnected assembly of solar cells (also referred to as “solar wafers” or “photovoltaic cells”). FIG. 1(a) illustrates a conventional solar panel 1 including an assembly of solar cells 2 interconnected in a two-dimensional array. Solar panels use light energy (photons) from the sun to generate electricity through photovoltaic effect (i.e., the photo-electric effect). In a solar panel, the solar cells are connected electrically in series and in parallel to generate the desired output voltage and output current. Because a single solar panel can only produce a limited amount of power, most photovoltaic installations involves connecting multiple solar panels into an array. A photovoltaic system or a solar system typically includes an array of solar panels, an inverter, batteries and interconnection wiring.

In particular, solar cells in a solar panel are also usually connected in series to create an additive voltage and connected in parallel to yield a higher current. Solar panels are then interconnected, in series or parallel, or both, to create an array providing the desired peak DC voltage and current.

Once the solar cells are assembled into a panel, there is limited access to identify or monitor the individual solar cells. Should any one cell in a solar panel malfunctions, or any one solar panel in a solar array malfunctions, and there will be a claim of warranty replacement or repair by user, but solar panel suppliers have only limited ability to monitor the output performance of the solar cells or solar panels throughout their operational life, in order to validate the warranty claim. This makes product failure analysis and quality correlation study difficult and economically challenging. Inability to remotely monitor individual solar cell or individual solar panel often leads to excess cost over the life time of the panel, also requires more labor maintenance or repairing or expensive replacement.

### SUMMARY OF THE INVENTION

According to one embodiment of the present invention, a solar panel includes an assembly of interconnected photovoltaic cells, a top plate configured to affix to a front side (sun up side) of the assembly of interconnected photovoltaic cells, a back sheet configured to affix to a back side of the assembly of interconnected photovoltaic cells, a wireless tracking device placed between the top plate and the back sheet of the solar panel where the wireless tracking device includes a wireless communication interface and a memory, and an antenna formed on or in the solar panel and in electrical communication with the wireless communication interface of the wireless tracking device. The memory of the wireless tracking device is configured to store at least identification and identity information of the solar panel or identification and identity information of one or more of the photovoltaic cells of the solar panel. The information stored in the memory is accessible through the wireless communication interface of the wireless tracking device.

According to another aspect of the present invention, a solar panel includes an assembly of interconnected photovoltaic cells, a top plate configured to affix to a front side (sun up side) of the assembly of interconnected photovoltaic cells, a back sheet configured to affix to a back side of the assembly of interconnected photovoltaic cells, and a wireless tracking and monitoring device. The wireless tracking and monitoring device includes a wireless communication interface, one or more sensors configured to measure one or more operational parameters of the solar panel or the photovoltaic cells where the one or more sensors generates measured sensor values, a processor configured to process measured sensor values, a memory configured to store at least identification and identity information of the solar panel or identification and identity information of one or more of the photovoltaic cells of the solar panel, and an interface bus coupled between the processor and the memory and between the processor and the wireless communication interface to provide the processed sensor values to the memory or to the wireless communication interface. At least the wireless communication interface and the memory of the wireless tracking and monitoring device are affixed to an exposed side of the back sheet at a location inside the junction box interface. The wireless tracking and monitoring device is enclosed by a junction box housing attached to the junction box interface.

The solar panel further includes an antenna formed on or in the solar panel and in electrical communication with the wireless communication interface of the wireless tracking and monitoring device. In operation, the information stored in the memory is accessible through the wireless communication interface of the wireless tracking and monitoring device.

### BRIEF DESCRIPTION OF THE DRAWINGS

FIG. 1(a) illustrates a conventional solar panel including an assembly of solar cells interconnected in a two-dimensional array.

FIG. 1(b) illustrates a conventional single solar cell including two bus bars forming the electrical contacts of the solar cell.

FIG. 2 illustrates a solar panel incorporating a wireless device for wireless tracking and monitoring according to one embodiment of the present invention.

FIG. 3 illustrates the back side of a solar panel incorporating an embedded wireless device for wireless tracking and monitoring according to one embodiment of the present invention.

FIG. 4 is a block diagram of a wireless tracking device according to one embodiment of the present invention.

FIG. 5 is a block diagram of a wireless tracking and monitoring device according to one embodiment of the present invention.

FIG. 6(a) and FIG. 6(b) are cross-sectional views of the solar panel of FIG. 2 across a line A-A′ according to embodiments of the present invention.

FIG. 7 illustrates an exemplary solar panel structure for a crystalline silicon solar cell and further illustrates the insertion of the wireless device of the present invention according to embodiments of the present invention.

FIG. 8 illustrates an exemplary solar panel structure for a thin film solar cell and further illustrates the insertion of the wireless device of the present invention according to embodiments of the present invention.

FIG. 9 illustrates an exemplary solar panel structure for a thin film solar cell and further illustrates the insertion of the wireless device of the present invention according to embodiments of the present invention.

FIG. 10(a) and FIG. 10(b) are cross-sectional views of the solar panel of FIG. 2 across a line B-B′ according to embodiments of the present invention.

FIG. 11(a) and FIG. 11(b) are cross-sectional views of the solar panel of FIG. 2 across a line B-B′ according to alternate embodiments of the present invention.

FIG. 12 is a schematic diagram of a wireless tracking and monitoring device according to one embodiment of the present invention.

FIG. 13 is a system diagram of a solar array installation according to one embodiment of the present invention.

FIG. 14 illustrates the back side of a solar panel including a wireless device according to one embodiment of the present invention.

FIG. 15 illustrates the back side of a solar panel including a wireless device according to an alternate embodiment of the present invention.

### DETAILED DESCRIPTION OF THE PREFERRED EMBODIMENTS

According to one aspect of the present invention, a wireless device is embedded in a solar panel for providing remote tracking and/or performance monitoring of the solar panel. In one embodiment, the wireless device is a wireless tracking device for providing tracking function. The wireless tracking device includes a memory for storing the identification or identity information of the solar panel or the identification or identity information of the individual solar cells forming the panel. The wireless tracking device implements wireless communication to allow the stored identification and identity information to be retrieved through wireless communication, such as using radio frequency (RF). In this manner, the identity of a solar panel or the individual solar cells making up the solar panel can be accessed remotely using a wireless reader device. The wireless tracking device is particularly useful when the solar panel is incorporated in an array installation and allows the individual solar panel to be identified wirelessly by coming within the vicinity of the solar panel, without having to disassemble or removing the solar panel from the installation. An antenna for facilitating the wireless communication can be formed on or embedded within the solar panel.

In another embodiment, the wireless device is a wireless tracking and monitoring device embedded in a solar panel to provide both tracking and performance monitoring functions. Besides storing the identification or identity information of the solar panel or the individual solar cells forming the panel, the wireless tracking and monitoring device also functions to measure one or more operational parameters associated with the solar panel or the solar cells. The measured performance data can be stored in the memory of the wireless track and monitoring device or the performance data can be transmitted directly to external devices through a wireless communication link. The performance data or the stored information can be accessed using a wireless reader device. In this manner, the performance of the individual solar panel can be remotely monitored before or after the solar panel is incorporated in an array installation. Furthermore, performance monitoring can be conducted throughout the lifetime of the solar panel.

When the wireless device is embedded in the solar panel, integration of the wireless device is transparent to the end user of the solar panel and does not increase or alter the size of the solar panel. Conventional solar panel monitoring systems usually require a separate circuit module to be attached to the outside of the solar panel. Conventional monitoring systems that are external to the solar panel are more costly to install and are not tamper resistant. The wireless device of the present invention is integrated into or embedded in each solar panel so that the monitoring device is convenient, wireless, and cheaper to the user and is tamper resistant.

According to another aspect of the present invention, a wireless tracking and monitoring device is placed on the exposed side of the back sheet of a solar panel at a location inside the junction box interface of the solar panel. The wireless tracking and monitoring device is then enclosed inside the junction box housing when the junction box is attached to the solar panel. In some embodiments, elements of the wireless tracking and monitoring device, such as the sensors or the processor, may be embedded inside the solar panel while the remaining elements are placed on the external back sheet at a location within the area of the junction box interface.

In the present description, a solar panel or solar module refers to an assembly of solar cells (or photovoltaic cells or solar wafers) for generating electricity through photovoltaic effect. The most commonly used solar cells are wafer-based crystalline silicon cells. Crystalline silicon cells include monocrystalline silicon wafer cells or polycrystalline silicon wafer cells. Monocrystalline silicon wafer cells generally have gaps at the four corners of the cells because the wafers are cut from cylindrical ingots. Polycrystalline silicon wafer cells are cut from square ingots and generally do not have gaps at the corners of the cells.

Other commonly used solar cells are thin film solar cells. Thin film solar cells are formed by depositing thin-films on a supporting substrate. The thin films can include amorphous silicon or cadmium telluride (CdTe) or others. The supporting substrate can be a silicon substrate, a glass plate or a stainless steel sheet or other compatible supporting substrates. Typically, a transparent conducting oxide layer is formed on the front (sun up) side of the thin film solar cells to form the front electrical contact. Another transparent conducting oxide layer or a metal layer forms the back side electrical contact.

In general, a solar panel includes an optically transparent layer on the front (sun up) side (also referred to as a “top plate”), allowing light to pass while protecting the solar wafers from the elements (rain, hail, etc.). The solar panel may also include a backside support (also referred to as the “back sheet”), typically made of plastic, such as polyethylene terephthalate (PET) or polycarbonate or other plastic materials. The top plate and the back sheet are secured in a frame, such as an aluminum alloy frame. A solar panel also includes a junction box for housing the electrical connections between the electrical contacts from the solar cells and the cable connectors out of the panel.

In a solar cell, electrons generated by the photovoltaic effect have to flow from one side of the cell to the other through an external circuit. Accordingly, electrical contacts are formed on both sides of the solar cells. To minimize conduction loss while also minimizing light obstruction, solar cells are typically covered by a metallic contact grid that shortens the distance the electrons have to travel while covering only a small part of the solar cell surface. Typically, solar cells are formed including one or more conductive traces on the solar cell surfaces, also refer to as “bus bars”, which are soldered to the solar cell surface to connect to the metallic contact grid system. In some cases, the conductive traces are formed using silver and are referred to as “silver bars.” In other cases, the conductive traces are formed using solder strips.

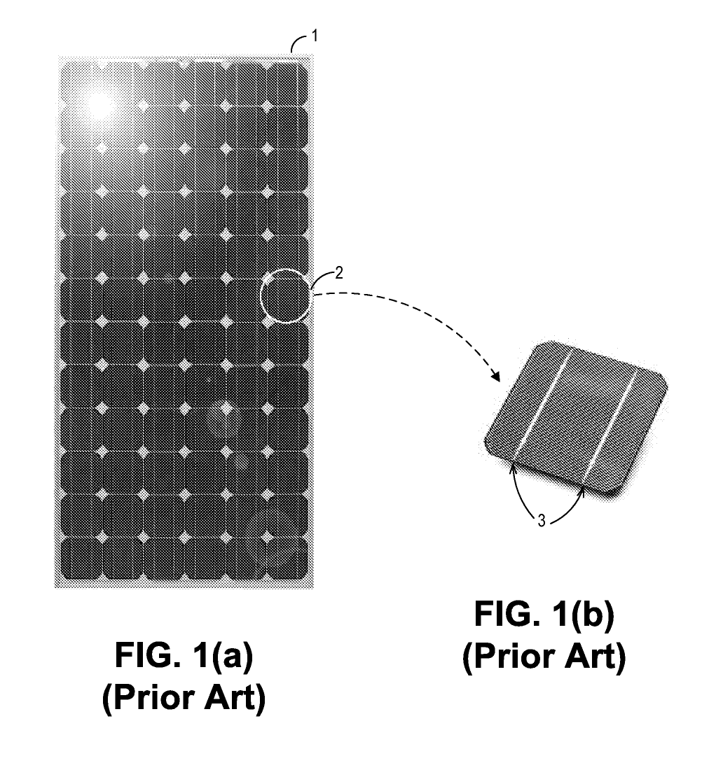

FIG. 1(b) illustrates a single solar cell 2 including two bus bars 3 forming the electrical contacts of the solar cell. Solar cell 2 includes bus bars 3 formed on the front side (sun up) and also the back side (not shown) of the solar cell. Solar cell 2 are connected in series to form a column of the solar panel 1 by connecting the bus bars on the front side of one solar cell to the bus bars on the back side of the next solar cell and so on. Conductive wires or traces connect the bus bars at the ends of the columns of solar cells to form a serial or parallel connection from the columns of solar cells.

Embedded Wireless Device

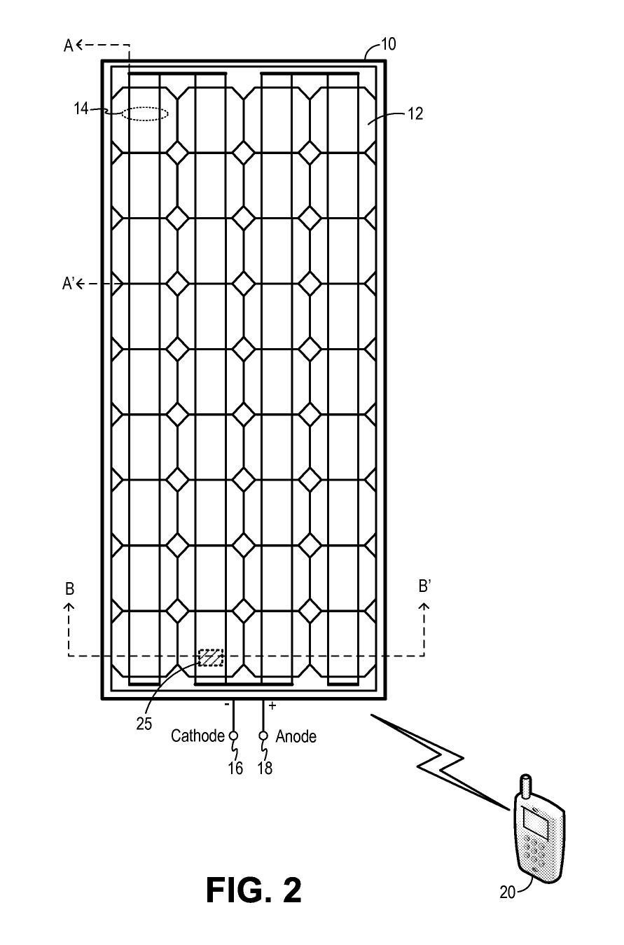

FIG. 2 illustrates a solar panel incorporating a wireless device for wireless tracking and monitoring according to one embodiment of the present invention. Referring to FIG. 2, a solar panel 10 includes an assembly of a two-dimensional array of interconnected solar cells 12. In the present illustration, each solar cell 12 includes two conductive traces (bus bars) 14 formed on the front side and two conductive traces (bus bars) formed on the back side (not shown) of the solar cell. In the present illustration, the bus bars 14 are connected at the ends of the solar panel 10 to form a serial connection of solar cells. Solar panel 10 includes external connectors 16 and 18 for connecting to the most positive node (the Anode) and the most negative node (the Cathode) of the solar panel.

In accordance with embodiments of the present invention, a wireless device 25 is embedded in the solar panel 10 to enable wireless communication with a wireless reader device 20. More specifically, the wireless device 25 is placed between the top plate and the back sheet of solar panel 10 so that the wireless device is completely contained within the solar panel. In the present embodiment, the wireless device 25 is placed on the back side of or beneath the solar cells 12 so that the wireless device 25 does not obscure the light sensitive surface of the solar cells. In some embodiments, wireless device 25 is a wireless tracking device which stores identity or identification information of the solar panel 10 or the solar cells 12 of the solar panel. In other embodiments, wireless device 25 is a wireless tracking and monitoring device for storing identity and identification information and also for monitoring the performance of the solar panel. Identity and identification information as well as performance data may be stored in the wireless device 25 and may be retrieved using wireless reader device 20. In this manner, identification data or performance data of the solar panel 10 may be accessed remotely and wirelessly without requiring the solar panel to be disassembled from an installation. The wireless tracking device and the wireless tracking and monitoring device will be described in more detail below.

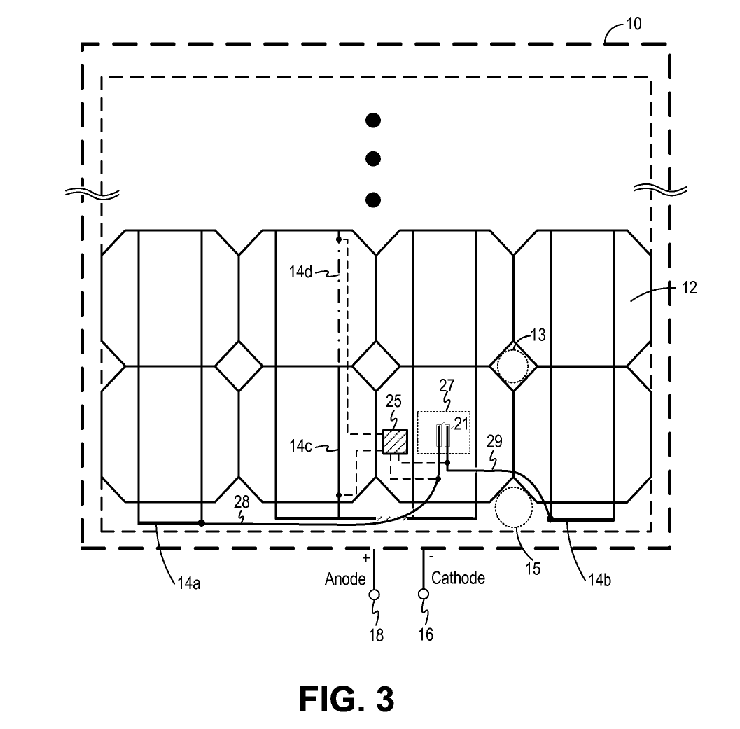

FIG. 3 illustrates the back side of a solar panel incorporating an embedded wireless device for wireless tracking and monitoring according to one embodiment of the present invention. Like elements in FIGS. 2 and 3 are given like reference numerals to simplify the discussion. Referring to FIG. 3, the wireless device 25 is placed between the back side of a solar cell 12 and the back sheet of the solar panel. In the case where the wireless device 25 is a wireless tracking and monitoring device, wireless device 25 includes electrical connections to metal traces or bus bars of solar panel 10 to facilitate measurements of performance data of the solar panel 10, as will be described in more detail below.

In the solar panel 10, a junction box is placed on the back side of the solar panel to form the external connectors of the solar panel. The external connectors are represented by cathode and anode terminals 16 and 18 in FIG. 3. A junction box interface 27 is thus formed on the back side of the back sheet of the solar panel 10. Junction box interface 27 includes conductive traces 21 which are exposed, i.e., not covered by the back sheet of the solar panel. A junction box housing is placed on top of the junction box interface and includes connectors, such as a metal screw, for making electrical contact with the conductive traces 21, thereby forming the external connectors of the solar panel. In the present description and as shown in FIG. 3, the dotted line box 27 indicates the location where the housing of the junction box will be placed over the conductive traces 21. In actual implementation, the junction box interface does not have any physical features indicating the boundary of the interface. The dotted line box 27 is illustrative only.

In the embodiment shown in FIG. 3, the wireless device 25 is placed on the back side of a solar cell 12. In other embodiments of the present invention, the wireless device 25 can be placed on the front side of the solar cell 12 between the top plate and the solar cell 12. Because the wireless device 25 is typically very small as compared to the solar cell, obstruction of the light sensitive area is only minimal. In other embodiments, the wireless device 25 may be placed in the gaps at the corners of the solar cells 12 (denoted by dotted circle 13), if such gap exists, or in a space adjacent the solar cells 12 (denoted by dotted circle 15). The exact placement of the wireless device 25 is not critical to the practice of the present invention.

In embodiments of the present invention, the wireless device 25 in FIGS. 2 and 3 is fabricated on a flexible circuit board and has dimensions on the order of tens to hundreds of millimeter and a thickness of 0.5 mm or less. In some embodiments, the wireless device 25 has dimensions in the range of 25 mm to 150 mm and has a thickness in the range of 0.35 mm to 0.45 mm. The wireless device 25 can be form of any dimension and thickness suitable for being embedded into the solar panel. The exact dimension or thickness of the wireless device is not critical to the practice of the present invention.

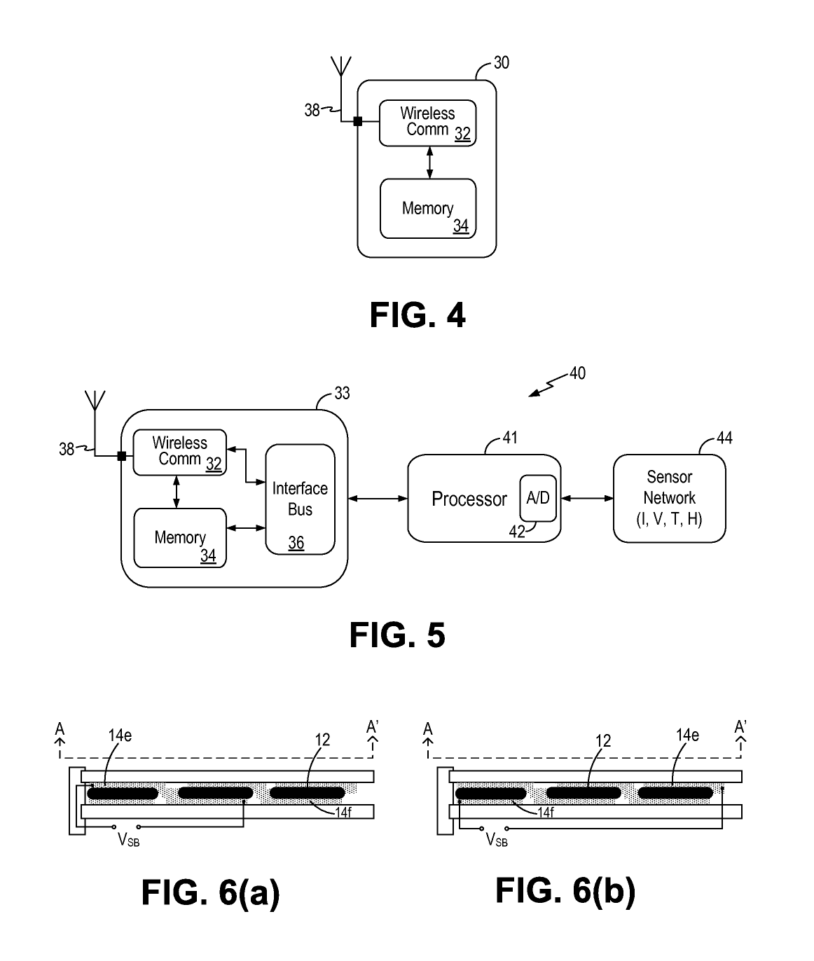

FIG. 4 is a block diagram of a wireless tracking device according to one embodiment of the present invention. Referring to FIG. 4, a wireless tracking device 30 can be used to implement the wireless device of FIGS. 2 and 3 when only tracking function is desired. In the present embodiment, the wireless tracking device 30 includes a wireless communication interface 32 and a memory 34. In the present embodiment, wireless communication interface 32 implements radio frequency (RF) communication. Furthermore, in the some embodiments, memory 34 is a non-volatile memory. In one embodiment, the memory 34 is implemented as an electrically erasable programmable read-only-memory (EEPROM). Furthermore, in another embodiment, the memory 34 is implemented as a dual port EEPROM. In other embodiments, other non-volatile memory devices can be used. The memory 34 is disposed to store information relating to the solar panel or the solar cell forming solar panel. In some embodiments, the memory 34 stores identification and identity information of the solar panel or identification and identity information of the one or more solar cells forming the solar panel. The memory 34 may also store other information such as manufacturer, processing history, installation history of the solar panel or the solar cells forming the solar panel.

The wireless tracking device 30 is coupled to an antenna 38 to transmit and receive wireless communication through the wireless communication interface 32. In some embodiments, the antenna 38 is formed as conductive traces embedded in the solar panel. In other embodiments, antenna 38 is formed as conductive traces on the exterior surface of the solar panel, either on the sun up side or on the back sheet side. In some embodiments, the antenna 38 is provided with sufficient length to realize a reception range of 0.5 meters to 10 meters or greater.

In one embodiment, the wireless tracking device 30 is implemented as a radio frequency identification (RFID) device. The antenna 38 may be integrated with the RFID device or may be provided separately on or in the solar panel as described above. The RFID device and the antenna together form what is commonly known as an RFID tag. The wireless tracking device 30 can be implemented as a passive RFID or an active RFID. In a passive RFID, the wireless communication interface 32 and the memory 34 is powered by the energy received on the antenna 38 of the RFID tag. As an active RFID, the wireless tracking device 30 is powered by a voltage of the solar panel or powered by a battery power source.

FIG. 5 is a block diagram of a wireless tracking and monitoring device according to one embodiment of the present invention. Referring to FIG. 5, a wireless tracking and monitoring device 40 can be used to implement the wireless device of FIGS. 2 and 3 when both tracking and performance monitoring function are desired. In the present embodiment, the wireless tracking and monitoring device 40 includes a wireless tracking device 33, a processor 41 and one or more sensors 44. The wireless tracking device 33 is implemented in the same manner as the wireless tracking device 30 of FIG. 4 with the addition of an interface bus 36 provided for communicating with the processor 41. Like elements in FIGS. 4 and 5 are given like reference numerals to simplify the discussion. In some embodiments, the interface bus 36 is a serial data bus or an 12C data bus. Other data bus configuration may also be used. The wireless tracking device 33 is coupled to an antenna 38 formed either in or on the solar panel, as discussed above.

In operation, the interface bus 36 provides communication between the processor 41 and the memory 34 for storing sensor data obtained form the one or more sensors 44. The interface bus 36 also provides communication between the processor 41 and the wireless communication interface 32 to allow the sensor data to be directly transmitted out of the wireless tracking device without being stored in the memory 34.

The one or more sensors 44 of the wireless tracking and monitoring device 40 are disposed to measure one or more operational parameters of the solar panel or the solar cells. In embodiments of the present invention, sensors 44 includes sensors for measuring at least the solar panel current, the solar panel voltage, the solar cell temperature and the humidity of the assembly of solar cells. Other sensors for measuring other operational parameters of the solar panel or the solar cells may also be used. The measured sensor values from the sensors 44 are provided to the processor 41 to process the measured sensor values. In some embodiments, the processor 41 includes an analog-to-digital converter 42 to digitize the measured sensor values. The processor 41 may also performs other operations on the sensor data, such as calibrating the sensor values. The processor 41 provides the processed sensor values to the interface bus 36. The processed sensor values can be stored in the memory 34 or they can be provided to the wireless communication interface 32 to be transmitted out of the antenna 38 directly.

As thus constructed, the memory 34 is disposed to store identification and identity information associated with the solar panel or the solar cells forming the solar panel. The memory 34 is also disposed to store processed sensor values obtained from the processor 41. The information stored in the memory 34 may be retrieved remotely through the use of a wireless reader device realizing wireless communication with the wireless communication interface 32.

In some embodiments, the processor 41 of the wireless tracking and monitoring device 40 is powered by the solar panel or by a battery power source while the wireless tracking device 33 is passively powered by the energy received on the antenna 38. In other embodiments, the entire wireless tracking and monitoring device 40 may be powered by the solar panel or by a battery power source.

In embodiments of the present invention, sensors 44 for measuring the solar panel current and the solar panel voltage are electrically connected to the most positive voltage node and the most negative voltage node of the solar panel. The solar panel voltage can be measured by detecting the voltage difference between the most positive voltage node and the most negative voltage node of the solar panel. The solar panel current can be measured through a sense resistor connected in series with the most positive voltage node or the most negative voltage node. The voltage drop across the sense resistor and the resistance of the sense resistor can be used to derive the solar panel current.

In embodiments of the present invention, the sensor 44 for measuring the solar cell temperature is electrically connected to the bus bars of the solar cells and the solar cell temperature is determined by measuring the voltage drop across a portion of a bus bar on the solar cells. More specifically, the voltage drop across a portion of a bus bar is used to derive a resistance value associated with the portion of the bus bar. The resistance value of the bus bar is indicative of the temperature of the solar cell based on the known resistance-temperature relationship of the material used to form the bus bar. For instance, when the bus bars are formed as silver bars, the temperature-resistance relationship of the silver bar is well known. Thus, by measuring the resistance of the silver bar, the true or proximate solar cell temperature can be obtained. Furthermore, since the bus bar is residing directly on the solar cell, it is in close proximity to the PN junction interface of the solar cell. Hence, the temperature measurement using the bus bar will be much more accurate than using a thermal couple or other temperature sensor embedded inside the solar panel abut away from the solar cell PN junction.

According to embodiments of the present invention, the sensor 44 of the wireless tracking and monitoring device 40 can be configured to measure the voltage across a segment of the bus bar, or a section of the bus bar or the bus bar over the entire solar panel. FIG. 6(a) and FIG. 6(b) are cross-sectional views of the solar panel 10 of FIG. 2 across a line A-A′ according to embodiments of the present invention. As shown in the cross-sectional views of FIGS. 6(a) and 6(b), each solar cell 12 includes a bus bar 14e on the front side and a bus bar 14f on the back side of each cell. To connect the solar cells in series, the front side bus bar 14e of one solar cell is connected to the back side bus bar 14f of the next cell and so on to form a serial chain of solar cells. In the present description, measuring a “segment” of the bus bar refers to measuring a contiguous portion of the bus bar between two adjacent solar cells, as shown in FIG. 6(a), without crossing over any PN junction of a solar cell. In the present description, measuring the voltage across a “section” of the bus bar refers to measuring a portion of the bus bar across one or more solar cells, as shown in FIG. 6(b). In one embodiment, the voltage can be measured across the entire panel by measuring between the silver bar at the first solar cell and the silver bar at the last solar cell of the sole cell chain. In the case where the voltage measurement is performed across a PN junction of a solar cell, the voltage drop, and hence the resistance, of the solar cell is also included in the voltage measurement, such that a composite voltage measurement or composite resistance measurement is obtained. However, the solar cell resistance may be calibrated out or the composite resistance may be characterized to provide the temperature dependence resistance value of the entire solar panel.

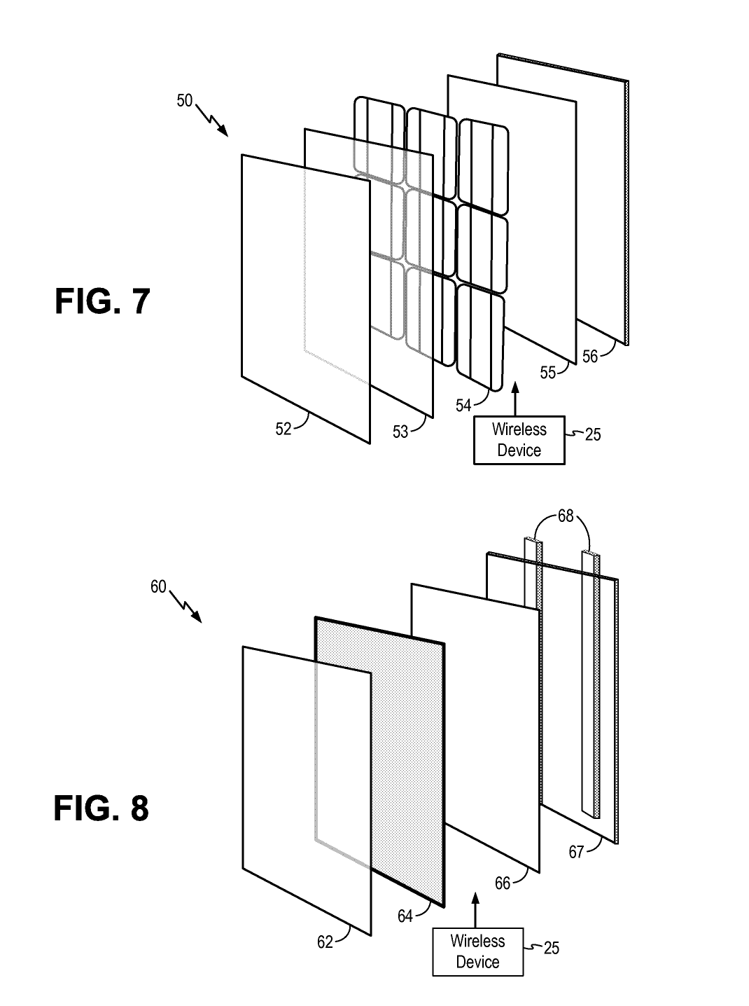

FIGS. 7-9 illustrate three exemplary solar panel structures and further illustrate the insertion of the wireless device of the present invention according to embodiments of the present invention. Referring first to FIG. 7, a solar panel 50 is formed of crystalline silicon solar cells 54. The solar panel 50 includes a top plate 52 affixed to the front side (sun up side) of the solar cells 54 and a back sheet 56 affixed to the back side of the solar cells 54. In some embodiments, the top plate 52 is a glass layer. In another embodiment, the top plate is formed using an optically transparent polymer film, such as DuPont Teflon film. In the present description, the term “top plate” refers to an optically transparent layer suitable for use as the cover layer for the top side (or sun up side) of a solar panel, which can include a glass layer, a Teflon film, or other optically transparent polymer film.

In one embodiment, the back sheet is a polyvinyl fluoride sheet. In some embodiments, the top plate 52 is affixed to the front side of the solar cells 54 through a first interface layer 53. Furthermore, the back sheet 56 is affixed to the back side of the solar cells 54 through a second interface layer 55. In one embodiment, the first interface layer 53 is a transparent adhesive layer while the second interface layer 55 is an adhesive layer. In one embodiment, the first and second interface layers 53, 55 are formed as an ethylene vinyl acetate (EVA) film and become adhesive under heat treatment and becomes fully transparent after lamination. In another embodiment, the first and second interface layers 53, 55 are each an encapsulant layer, such as DuPont PV 8600 film.

In some embodiments, the wireless device 25 is inserted between the back side of the solar cells 54 and the second interface layer 55. In that case, the wireless device 25 is placed away from the sun sensitive surface of the solar cells and do not obstruct any sun sensitive area. In an alternate embodiment, the wireless device 25 is inserted between the front side of the solar cells 54 and the first interface layer. In yet another alternate embodiment, the wireless device 25 is placed in the gaps between the solar cells and is thus inserted between the first and second interface layers.

Referring next to FIG. 8, a solar panel 60 is formed of thin film solar cells 64. The solar panel 60 includes a top glass plate 62 with the thin film solar cells 64 formed on the back side of the top glass plate 62 (the back side being the side away from the sun up side). It is understood that a layer of transparent conductive oxide is formed both on the front and back sides of the thin film solar cells 64 to provide electrical conduction for the solar cells. A back sheet 67 is affixed to the back side of the solar cells 64. In some embodiments, the back sheet is a glass plate or a metal plate or other substrate coated with a metal layer. In some embodiments, the back sheet 67 is affixed to the back side of the solar cells 64 through an interface layer 66. In one embodiment, the interface layer 66 is an adhesive layer. In one embodiment, the interface layer 66 is formed as a polyvinyl butyral film and becomes adhesive under heat treatment. In another embodiment, the interface layer 66 is an encapsulant layer. Optional mounting rails 68 may be provided on the back side of the back sheet 67 to provide structural support. In some embodiments, the wireless device 25 is inserted between the back side of the solar cells 64 and the interface layer 66.

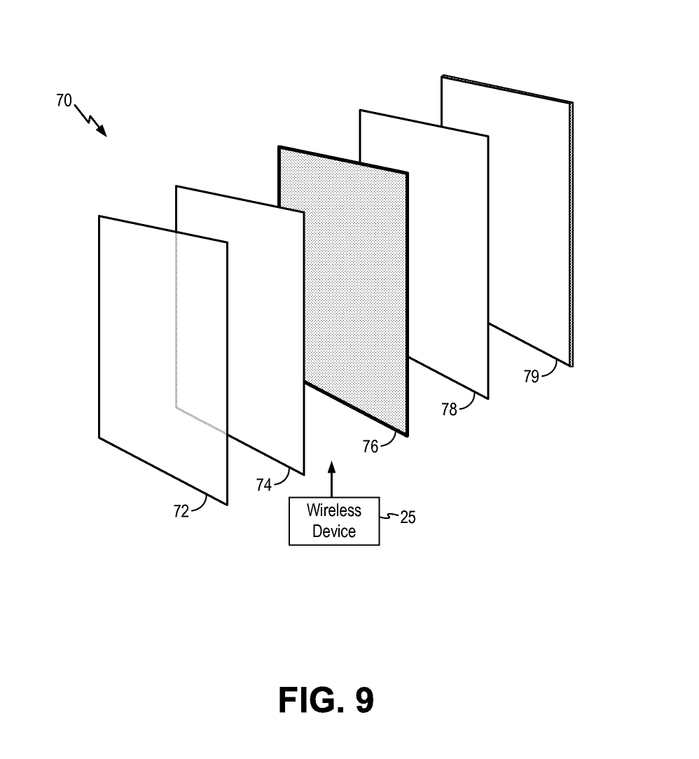

Referring next to FIG. 9, a solar panel 70 is formed of thin film solar cells 76. The solar panel 70 includes a top plate 72 and a back sheet 79. The thin film solar cells 76 are formed on the front side of a carrier substrate 78. It is understood that a layer of transparent conductive oxide is formed both on the front and back sides of the thin film solar cells 76 to provide electrical conduction for the solar cells. When the thin film solar cells 76 are formed on the carrier substrate 78, the top plate 72 may be a glass layer or an optically transparent polymer film, such as a Teflon film. In some embodiments, the carrier substrate is a silicon substrate, a glass layer or a stainless steel sheet. In some embodiments, the top plate 72 is affixed to the front side of the solar cells 76 through an interface layer 74. In one embodiment, the interface layer 74 is a transparent adhesive layer. In one embodiment, the interface layer 74 is formed as an EVA film and becomes adhesive under heat treatment and becomes fully transparent after lamination. In another embodiment, the interface layer 74 is an encapsulant layer. In some embodiments, the wireless device 25 is inserted between the front side of the solar cells 76 and the interface layer 74.

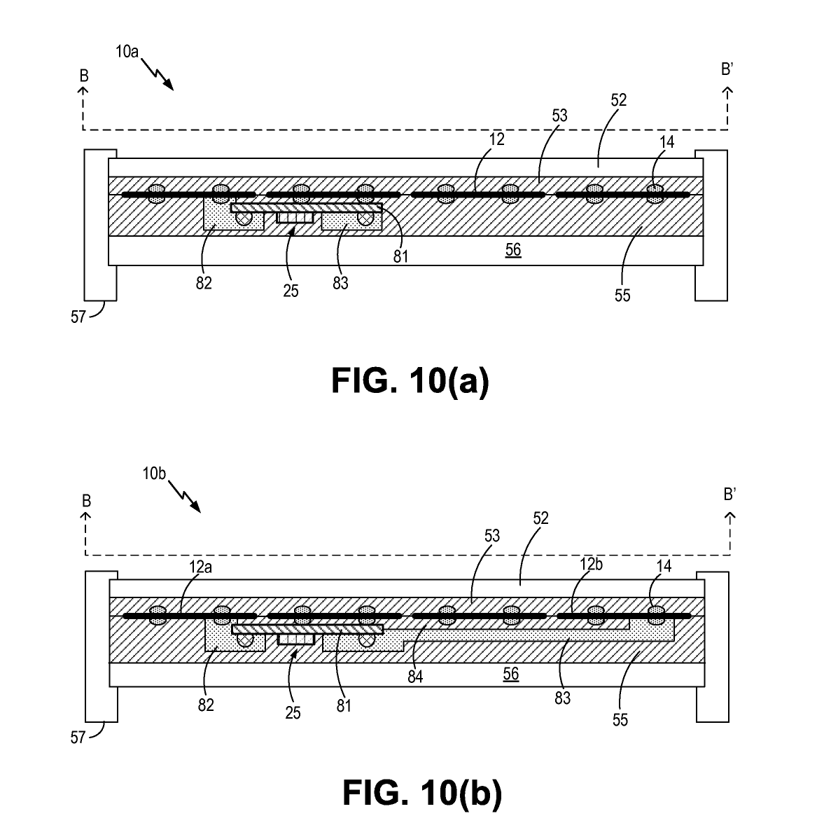

FIG. 10(a) and FIG. 10(b) are cross-sectional views of the solar panel 10 of FIG. 2 across a line B-B′ according to embodiments of the present invention. Referring first to FIG. 10(a), the solar panel 10 includes an array of solar cells 12, including bus bars 14 formed thereon, enclosed between a top plate 52 and a back sheet 56 and secured by a frame 57. In accordance with embodiments of the present invention, a wireless device 25 is placed at the back side of solar cells 12 between the solar cell 12 and the interface layer 55. The wireless device 25 makes electrical contact with a selected bus bar through conductive traces 82, 83. Conductive traces 82, 83 can be a combination of metal traces and conductive adhesive or solder ball joints. In FIG. 10(a), the wireless device 25 is configured to measure a segment of the bus bar so that connection to one end of the segment of the bus bar is shown while connection to the other end of the segment of the bus bar is not shown as it is in a perpendicular direction to the cross-section. In FIG. 10(b), the wireless device 25 is configured to measure the entire silver bar line from the first solar cell 12a to the last solar cell 12b. Conductive traces 82, 83 and solder ball joints are used to connect the end points of the bus bars to the wireless device 25. In the embodiment shown in FIG. 10(b), an additional interface layer 84 may be used to insulate the conductive traces of the wireless device 25 from the solar cells 12.

In some embodiments, the wireless device 25 is fabricated on a flexible substrate, such as PET film or mylar film or Kapton film or other compatible plastic films. In other embodiments, the wireless device 25 may be fabrication using printed circuit board (PCB) substrate technology or other high density interconnect substrate technologies.

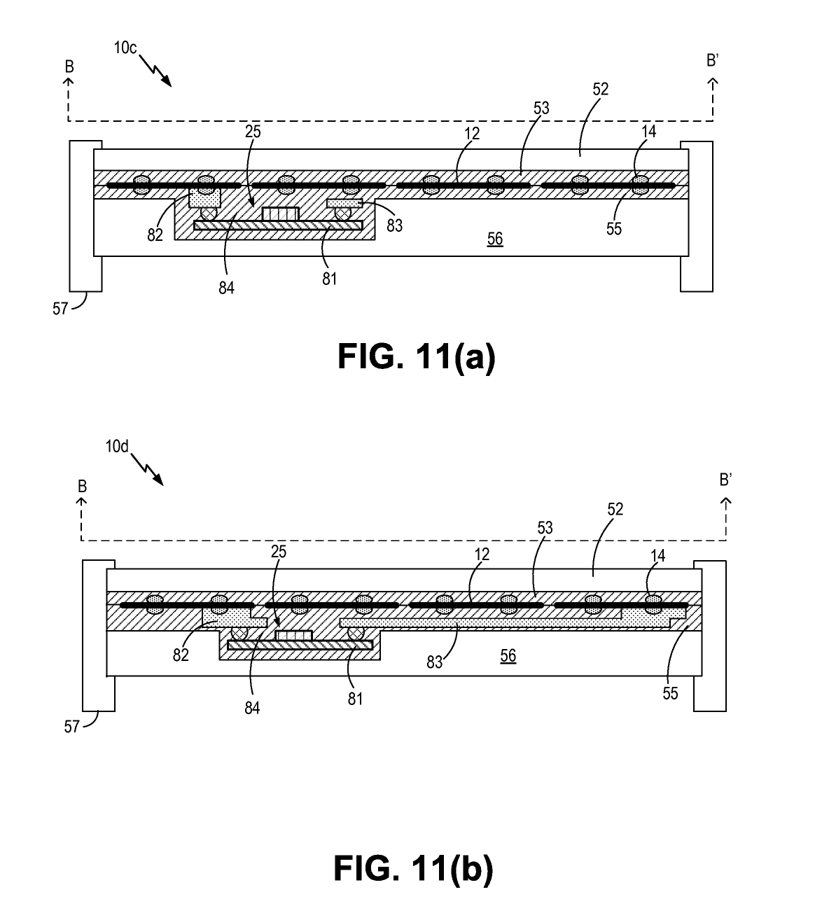

FIG. 11(a) and FIG. 11(b) are cross-sectional views of the solar panel 10 of FIG. 2 across a line B-B′ according to alternate embodiments of the present invention. Like elements in FIGS. 10(a) and 10(b) and FIGS. 11(a) and 11(b) are given like reference numerals to simplify the discussion. In the embodiments shown in FIGS. 11(a) and 11(b), the wireless device 25 is formed on a PCB substrate or a flexible substrate or other equivalent high density circuit board and is placed at the back side of the solar cells 12 with the active circuitry of the wireless device 25 facing towards the solar cells 12. An additional interface layer 84 may be used to insulate the wireless device and/or the conductive traces from the solar cells 12. The wireless device 25 makes electrical contact with a selected bus bar through conductive traces 82, 83, in the same manner as described above.

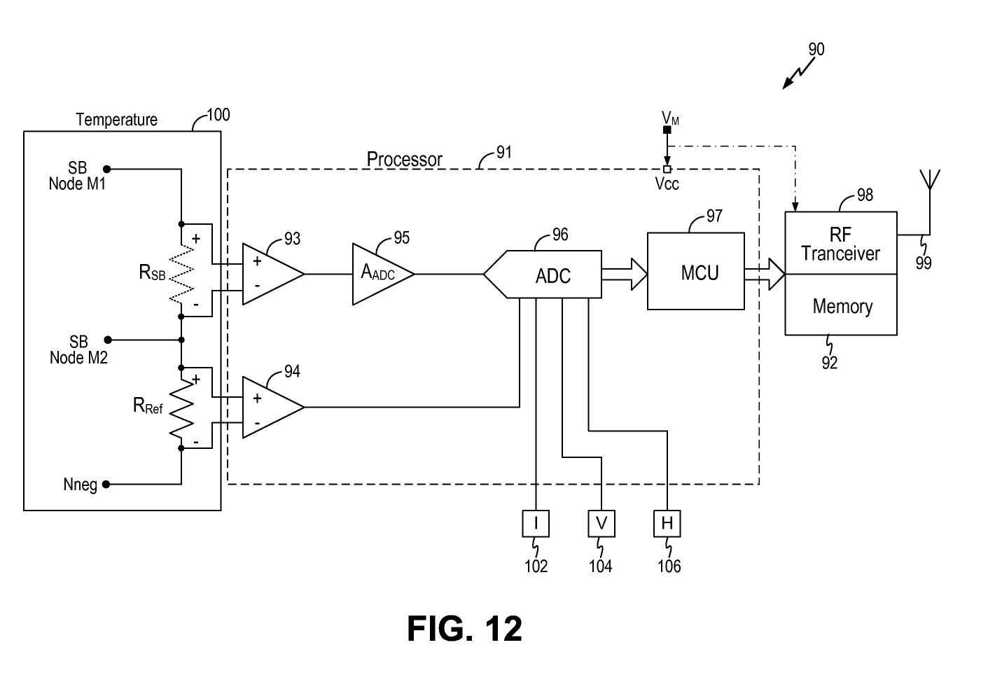

FIG. 12 is a schematic diagram of a wireless tracking and monitoring device according to one embodiment of the present invention. Referring to FIG. 12, a wireless tracking and monitoring device 90 includes a first measurement node (Node M1) and a second measurement node (Node M2) which are electrically coupled to a portion of the bus bar of a solar cell for temperature measurement. The portion of the bus bar being measured can be a segment, a section or the entire bus bar of the solar panel. The resistance of the portion of the bus bar being measured is denoted by a resistor R_{SB} in the present description. As described above, the first and second measurement nodes are connected to the respective measurement points through metal traces and/or solder joints. The first and second measurement nodes are coupled to voltage measurement circuitry in processor 91 to determine the voltage across the measured portion. In the present embodiment, the first and second measurement nodes are coupled to a voltage amplifier 93 to measure the voltage differential at the two nodes. The detected analog voltage from measurement nodes M1 and M2 is amplified by an amplifier 95 before being provided to an analog-to-digital converter (ADC) 96 to be digitized.

The voltage measurement circuitry also includes a reference resistor R_{Ref} for providing measurement calibration. Reference resistor R_{Ref} is connected between measurement node M2 and a most negative voltage node Nneg of the solar panel. Reference resistor R_{Ref} receives the current flowing from the second measurement node M2 to the most negative voltage node Nneg of the solar panel. Because resistor R_{Ref} has a known resistance value, a reference voltage can be derived. In some embodiments, reference resistor R_{Ref} is a surface mounted precision resistor or surface mounted thin film resistor or embedded thin film resistor or other equivalent resistor. In some embodiments, reference resistor R_{Ref} has a resistance that is independent of temperature. That is, the resistance of reference resistor R_{Ref} does not vary appreciably over a given temperature range. The voltage across reference resistor R_{Ref} is measured by a voltage amplifier 94. The voltage measured by amplifier 94 is provided to ADC 96 to use as a reference voltage.

The wireless tracking and monitoring device 90 further includes one or more sensors 102, 104, 106 for measuring the solar panel current, the solar panel voltage and the humidity of the solar cells. The measured sensor values are typically analog values and are provided to the ADC 96 of the processor 91 to be digitized. Wireless tracking and monitoring device 90 further includes a math computation unit (MCU) 97 The digitized sensor values from ADC 96 are provided to MCU 97 to be processed, such as to be calibrated.

In one embodiment, the processed sensor values are stored in a memory 92 to be retrieved later by a wireless communication interface 98 through antenna 99. In another embodiment, the processed sensor values are provided to the wireless communication interface 98 directly for immediate transmission over antenna 99. In one embodiment, the wireless communication interface 98 is an RF transceiver for facilitating RF communication.

The memory 92 is also used to store identification information for the solar panel or the solar cells forming the solar panel. The stored identification information can be retrieved through the wireless communication interface 98. In this manner, the sensor data related to the performance of the solar panel or solar cells and the identification information of the solar panel or solar cells can be retrieved through wireless communication using a wireless reader, such as an RFID reader. In some embodiments, the memory 92 and the wireless communication interface 98 form an RFID tag with the added function of storing not only identification data but also solar panel performance data.

In one embodiment of the present invention, the processor 91 of the wireless tracking and monitoring device 90 is powered by the voltage of the solar panel V_{M}. In another embodiment, the processor 91 may be powered by a battery power source. The battery power source may be embedded in the solar panel or affixed to the exterior of the solar panel and electrically connected to the processor 91. In other embodiments, the wireless communication interface 98 and the memory 92 are powered passively from the energy received on the antenna 99. In yet other embodiments, the wireless communication interface 98 and the memory 92 may also be powered by the solar panel voltage V_{M} or the battery power source.

The wireless tracking and monitoring device of the present invention enables real time and precision monitoring of the solar panel performance. The wireless tracking and monitoring device also achieves superior form factor and tamper resistance. Through the use of an RFID tag to store identification information of the solar cells or the solar panel, verification of the authenticity of the solar cell or the solar panel can be made through a wireless reader to ensure system integrity.

Returning to FIG. 3, in one embodiment of the present invention, the wireless device 25 is a wireless tracking and monitoring device and is placed between the back side of the solar cells 12 and the back sheet of the solar panel 10. Furthermore, the wireless device 25 is placed close to the junction box interface 27. Placing the wireless device 25 close to the junction box interface 27 provides certain advantages. For example, sensors for measuring the solar panel current and the solar panel voltage may be connected to conductive traces 28, 29 connecting the most negative and the most positive voltage nodes of the solar panel to the junction box interface. Sensors for temperature measurement can be connected to an adjacent bus bar segment. In the present illustration, the wireless device 25 measures the solar cell temperature by connecting to a segment of a bus bar 14c formed on the back side of the solar cell and the contiguous bus bar 14d formed on the front side of the adjacent solar cell (shown as a dot-dash line). In this manner, the wireless device 25 can measure solar panel current, solar panel voltage and solar cell temperature using simple or minimal sensor circuitry.

In some embodiments, the wireless device 25 may be placed inside the area designated as the junction box interface 27 but still embedded within the back sheet of the solar panel. The exact placement of the wireless device 25 on solar panel 10 is not critical to the practice of the present invention as long as the wireless device 25 is embedded within the top plate and the back sheet of the solar panel.

Solar Array System

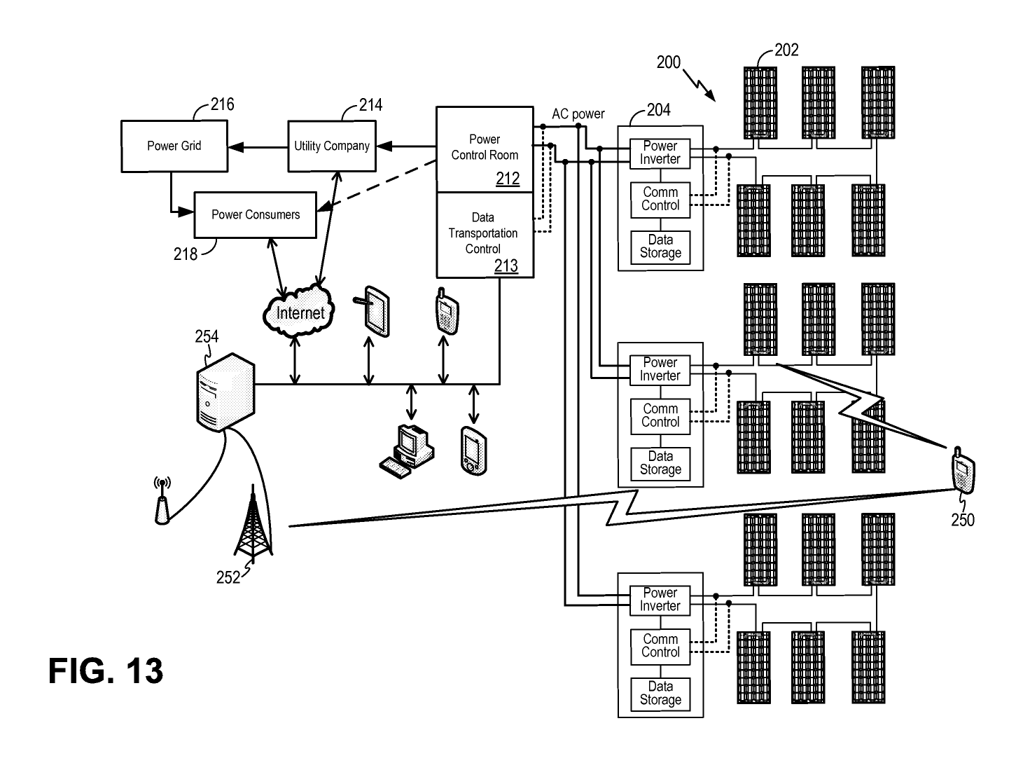

FIG. 13 is a system diagram of a solar array installation according to one embodiment of the present invention. Referring to FIG. 13, a solar array installation 200 includes one or more arrays of interconnected solar panel 202. The solar panels in each array may be connected in series (as shown) or in parallel. Each solar array is connected to a control unit 204 including a power converter, a communication control and data storage. Power generated by the solar array is converted to AC power at the power inverter and the AC power is transmitted to a power control room 212 and onto a utility company 214 where the power may be distributed to a power grid 216 and then to power consumers 218.

In accordance with the present invention, solar panels 202 in the solar array installation 200 are equipped with the wireless device in accordance with the present invention. Accordingly, a wireless reader device 250, coming into vicinity of the solar panels 202, may retrieve identity and identification information from the wireless device of each solar panel. If the wireless device includes monitoring functions, then wireless reader device 250 may also retrieve performance data from the wireless data of each solar panel.

In some embodiments, the retrieved information is transmitted wirelessly from the wireless reader device 250 through a base station 252 to a server 254. The server 254 may be connected to a local area network or to the Internet such that computing devices connected to the local area network or to the Internet may obtain the data collected by wireless reader device 250. In this manner, the identity and performance of a solar panel can be monitored wirelessly without requiring access to the solar panel front surface and the identity and performance data can be read by a wireless reader and analyzed at a location remote from the solar array installation.

According to embodiments of the present invention, a solar panel monitoring system includes a central control unit which may include a wireless reader device or may be in communication with a wireless reader device. The central control unit receives through wireless communication identification data stored in one or more of the solar panels 202 in the solar array installation 200. The central control unit may also receives through wireless communication performance data, such as solar panel current, solar panel voltage, solar cell temperate, or solar panel humidity, from the one or more of the solar panels 202 in the solar array installation 200. In another embodiment, the central control unit, through wireless communication with a wireless tracking and monitoring device incorporated in a solar panel 202, initiates sensor measurements at the wireless tracking and monitoring device. The wireless tracking and monitoring device, upon completion of the sensor measurements, may store the data in the memory awaiting retrieval by the central control unit. Alternately, the wireless tracking and monitoring device, upon completion of the sensor measurements, may transmit the performance data directly to the central control unit.

Fabrication Process

In some embodiments of the present invention, the wireless device, whether a wireless tracking device or a wireless tracking and monitoring device, is fabricated on a flexible circuit board. The integrated circuit (IC) chip(s) forming the wireless communication functions or the data monitoring and processing functions are attached to the thin film interconnect structure of the flexible circuit board using flip chip attachment or chip scale package (CSP) assembly techniques so as to keep the form factor of the wireless device small.

In some embodiments, solder bumps are used to connect the IC chips to the flexible circuit board and to minimize the overall thickness of assembled flexible device. In some embodiments, the height of the solder bump is in the range of 0.05 mm to 0.4 mm. The size of the solder bump is not critical and can be as large as the size of the wire bonding pad of the integrated circuit. In one embodiment, the size of the solder bump is in the range of 50 um to 100 um. The shape of the solder bump base on the IC chip surface is also not critical to the practice of the present invention. The shape of the solder bump can be octagon or hexagon or circular or other shapes. The shape of the post-reflow solder joint is also not critical to the practice of the present invention.

In some embodiments, the thickness of the IC chip is kept small to keep the overall form factor small. In some embodiments, the IC chip thickness is 0.4 mm or less. In other embodiments, the IC chip thickness is in the range of 0.15 mm to 0.3 mm. In some embodiments, backgrinding of the IC chip is performed to reduce the thickness of the IC chip to the desired level.

In some embodiments, to further improve the mechanical integrity of the wireless device, a under fill material and a gloptop material can be separately applied or be permuted to reinforce the attachment strength of the IC chips to the flexible circuit board. The under fill material is applied to fill the gaps between solder joints after the IC chip attachment by a dispenser. The gloptop material can be applied to encapsulate the flip chip or CSP attached IC chip and its solder joints. An appropriate heat treatment process is applied to cure the under fill material and the gloptop material to ensure better mechanical protection. In other embodiments, the solder joints can also be replaced by the isotropic or anisotropic conductive solder pastes or conductive inks or other conductive pastes.

Wireless Device External to Solar Panel

According to another aspect of the present invention, a wireless device is affixed to the exposed side of the back sheet of a solar panel at a location inside the junction box interface. In this manner, when the junction box is attached to the solar panel, the wireless device is enclosed by the junction box housing attached to the junction box interface. In embodiments of the present invention, the wireless device can be a wireless tracking device including a wireless communication interface and a memory. Alternately, the wireless device can be a wireless tracking and monitoring device including a wireless communication interface, a memory, an interface bus, a processor and one or more sensors. By affixing the wireless device on exposed side of the back sheet of the solar panel but inside the junction box interface, the wireless device is protected by the junction box housing, thereby protected from the environment.

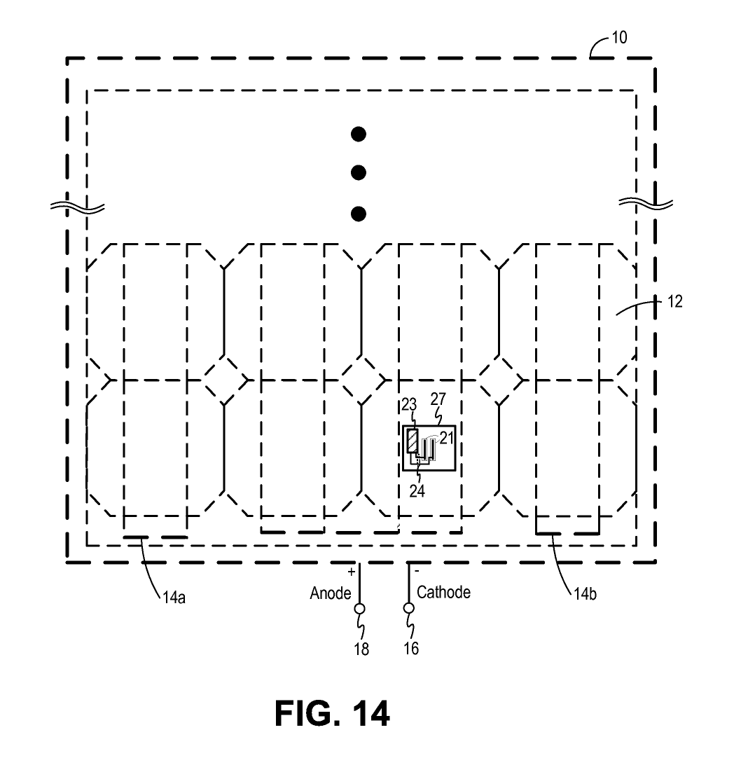

FIG. 14 illustrates the back side of a solar panel including a wireless device according to one embodiment of the present invention. Referring to FIG. 14, a wireless device 23 is affixed to the exposed side of the back sheet of the solar panel 10 in a location inside the area of the junction box interface 21. When the wireless device 23 is a wireless tracking and monitoring device, conductive traces 24 may be connected to the exposed junction box traces 21 to sense the solar panel voltage and the solar panel current. As thus configured, when the junction box housing is placed over the area designated as the junction box interface 27, the wireless device 23 is enclosed in the junction box housing and protected from the external elements.

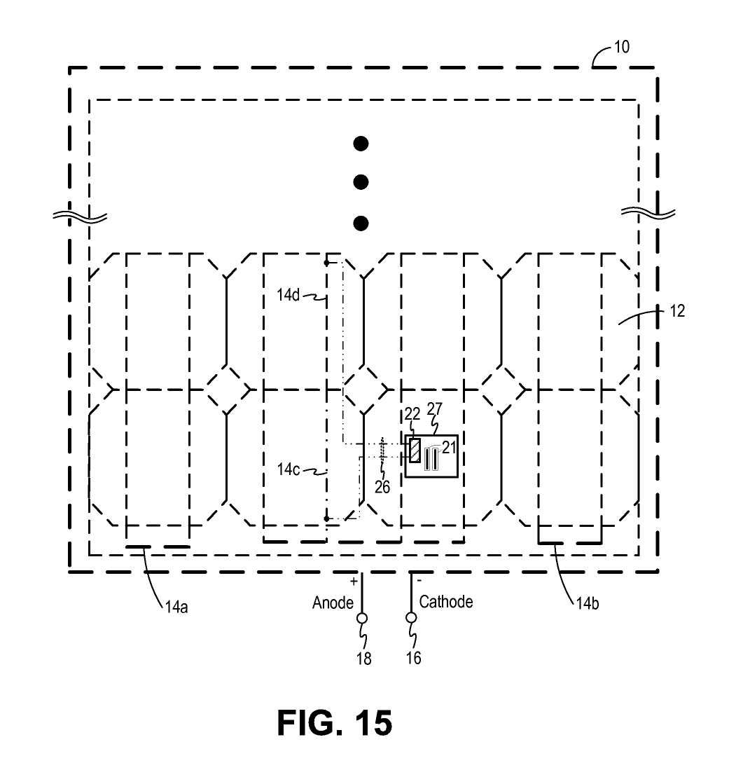

According to embodiments of the present invention, the wireless device is partially embedded within the solar panel with the remaining elements affixed to the exposed side of the back sheet but at a location inside the junction box interface. FIG. 15 illustrates the back side of a solar panel including a wireless device according to an alternate embodiment of the present invention. Referring to FIG. 15, a wireless device is a wireless tracking and monitoring device including a wireless communication interface, a memory, an interface bus, a processor and one or more sensors. In some embodiments, at least some of the elements of the wireless tracking and monitoring device 22 are embedded within the solar panel while the remaining elements are formed on the exposed surface of the back sheet. In the embodiment shown in FIG. 15, the sensors of the wireless tracking and monitoring device 22 are embedded within the solar panel 10. More specifically, conductive traces 26 for measuring the bus bar voltage are embedded within the solar panel 10 and electrically connected to the wireless tracking and monitoring device 22. Meanwhile, the processor, the interface bus, the memory and the wireless communication interface of device 22 are formed external to solar panel 10, affixed to the exposed back sheet of the solar panel but within the junction box interface 27.

In an alternate embodiment, both the processor and the sensors of the wireless tracking and monitoring device 22 are embedded inside solar panel 10 while the remaining elements, the interface bus, the memory and the wireless communication interface are formed on the exposed back sheet of the solar panel but within the junction box interface 27. Other levels of segregating the embedded elements and the non-embedded elements of the wireless device 22 are possible.

The wireless devices 22 and 23 of FIGS. 14 and 15 operate in the same manner as described above to provide tracking and performance monitoring function of the solar panel through wireless communication.

In the above descriptions, the identity or identification information is stored in a memory device of the wireless communication element or the Pure ID element. In the present description, a memory device refers to any charge storing device used in integrated circuits, including registers, random access memory, flash memory, volatile or non-volatile memories, or other suitable charge storing devices for storing one or more bits of data.

The above detailed descriptions are provided to illustrate specific embodiments of the present invention and are not intended to be limiting. Numerous modifications and variations within the scope of the present invention are possible. The present invention is defined by the appended claims.

We claim:

1. A solar panel comprising:
an assembly of interconnected photovoltaic cells;
a top plate configured to affix to a front side (sun up side) of the assembly of interconnected photovoltaic cells;
a back sheet configured to affix to a back side of the assembly of interconnected photovoltaic cells;
a wireless tracking device placed between the top plate and the back sheet of the solar panel, the wireless tracking device comprising a wireless communication interface and a memory; and
an antenna formed on or in the solar panel and in electrical communication with the wireless communication interface of the wireless tracking device,
wherein the memory of the wireless tracking device is configured to store at least identification and identity information of the solar panel or identification and identity information of one or more of the photovoltaic cells of the solar panel, the information stored in the memory being accessible through the wireless communication interface of the wireless tracking device.

2. The solar panel of claim 1, wherein the wireless tracking device is placed on the front side of one or more of the photovoltaic cells, or on the back side of one or more of the photovoltaic cells, or placed in a gap or a space adjacent to or between one or more of the photovoltaic cells.

3. The solar panel of claim 1, further comprising:
a first interface layer covering the front side of the assembly of interconnected photovoltaic cells; and
a second interface layer covering the back side of the assembly of interconnected photovoltaic cells,
wherein the top plate is configured to affix to the front side of the assembly of interconnected photovoltaic cells through the first interface layer and the back sheet is configured to affix to the back side of the assembly of interconnected photovoltaic cells through the second interface layer, and
wherein the wireless tracking device is embedded between the first interface layer and the second interface layer of the solar panel.

4. The solar panel of claim 3, wherein the first interface layer comprises a transparent adhesive layer and the second interface layer comprises an adhesive layer.

5. The solar panel of claim 3, wherein the first interface layer comprises a first encapsulant sheet and the second interface layer comprises a second encapsulant sheet.

6. The solar panel of claim 3, wherein the wireless tracking device is positioned on a front side or a back side of one or more photovoltaic cells and is electrically insulated from the photovoltaic cells by a third interface layer.

7. The solar panel of claim 1, wherein the wireless tracking device comprises a wireless tracking and monitoring device including the wireless communication interface and the memory, the wireless tracking and monitoring device further comprising:
one or more sensors configured to measure one or more operational parameters of the solar panel or the photovoltaic cells, the one or more sensors generating measured sensor values;
a processor configured to process measured sensor values; and
an interface bus coupled between the processor and the memory and between the processor and the wireless communication interface to provide the processed sensor values to the memory or to the wireless communication interface.

8. The solar panel of claim 7, wherein the processed sensor values are stored in the memory and the information stored in the memory are accessible through the wireless communication interface of the wireless tracking and monitoring device.

9. The solar panel of claim 7, wherein the processed sensor values are transmitted through the wireless communication interface of the wireless tracking and monitoring device without being stored in the memory.

10. The solar panel of claim 7, wherein the wireless tracking and monitoring device further comprises one or more sensors configured to measure a solar panel voltage, a solar panel current, a temperature value of the photovoltaic cells or a humidity value of the assembly of photovoltaic cells.

11. The solar panel of claim 10, wherein the one or more sensors of the wireless tracking and monitoring device are electrically connected to the solar panel or one or more photovoltaic cells to measure the solar panel voltage, the solar panel current and the temperature value of the photovoltaic cells.

12. The solar panel of claim 11, wherein the solar panel further comprises a junction box interface comprising conductive traces electrically connected to a most positive voltage node and a most negative voltage node of the solar panel, wherein the wireless tracking and monitoring device is positioned near or within the junction box interface and the one or more sensors are electrically connected to the most positive voltage node and the most negative voltage node of the solar panel to measure the solar panel voltage and the solar panel current.

13. The solar panel of claim 11, wherein each of the photovoltaic cell comprises at least one conductive bus bar formed on the front side and at least one conductive bus bar formed on the back side of the photovoltaic cell, the bus bar on the front side of one photovoltaic cell being connected to the bus bar on the back side of an adjacent photovoltaic cell to form a serial chain of photovoltaic cells being part of the assembly of interconnected photovoltaic cells.

14. The solar panel of claim 13, wherein the one or more sensors of the wireless tracking and monitoring device is electrically connected to a contiguous segment of the bus bar to measure a voltage value of the segment of the bus bar, the voltage value of the bus bar being indicative of the temperature of the photovoltaic cells.

15. The solar panel of claim 13, wherein the one or more sensors of the wireless tracking and monitoring device is electrically connected to a first end and a second end of the bus bars across one or more photovoltaic cells to measure a voltage value between the first end and the second end of the bus bars, the voltage value of the chain of bus bars being indicative of the temperature of the photovoltaic cells.

16. The solar panel of claim 7, wherein the processor comprises an analog-to-digital converter configured to digitize the measured sensor values.

17. The solar panel of claim 7, wherein the processor is powered by a voltage of the solar panel.

18. The solar panel of claim 7, further comprising a battery to supply power to the wireless tracking and monitoring device.

19. The solar panel of claim 1, wherein the antenna is formed as conductive traces embedded between the top plate and the back sheet of the solar panel.

20. The solar panel of claim 1, wherein the antenna is formed as conductive traces on a front side of the top plate of the solar panel or on a back side of the back sheet of the solar panel.

21. The solar panel of claim 1, wherein the wireless tracking device comprises a radio frequency identification (RFID) device, the RFID device being a passive RFID device powered by the energy received on the antenna or an active RFID device powered by a voltage of the solar panel.

22. The solar panel of claim 1, further comprising a battery to supply power to the wireless tracking device.

23. The solar panel of claim 1, wherein the photovoltaic cells comprise thin film photovoltaic cells, the thin film photovoltaic cells being formed on a back side of the top plate directly, the wireless tracking device being embedded between the thin film photovoltaic cells and the back sheet of the solar panel, the top plate being a glass layer.

24. The solar panel of claim 1, wherein the photovoltaic cells comprise thin film photovoltaic cells, the thin film photovoltaic cells being formed on a front side of a carrier substrate, the wireless tracking device being embedded between the thin film photovoltaic cells and the top plate of the solar panel.

25. The solar panel of claim 1, wherein the top plate comprises a glass layer or an optically transparent polymer layer.

26. A solar panel comprising:
an assembly of interconnected photovoltaic cells;
a top plate configured to affix to a front side (sun up side) of the assembly of interconnected photovoltaic cells;
a back sheet configured to affix to a back side of the assembly of interconnected photovoltaic cells; and
a wireless tracking and monitoring device comprising:
a wireless communication interface;
one or more sensors configured to measure one or more operational parameters of the solar panel or the photovoltaic cells, the one or more sensors generating measured sensor values;
a processor configured to process measured sensor values;
a memory configured to store at least identification and identity information of the solar panel or identification and identity information of one or more of the photovoltaic cells of the solar panel; and
an interface bus coupled between the processor and the memory and between the processor and the wireless communication interface to provide the processed sensor values to the memory or to the wireless communication interface,
wherein at least the wireless communication interface and the memory of the wireless tracking and monitoring device are affixed to an exposed side of the back sheet at a location inside the junction box interface, the wireless tracking and monitoring device being enclosed by a junction box housing attached to the junction box interface;
an antenna formed on or in the solar panel and in electrical communication with the wireless communication interface of the wireless tracking and monitoring device,
wherein the information stored in the memory is accessible through the wireless communication interface of the wireless tracking and monitoring device.

27. The solar panel of claim 26, wherein the one or more sensors of the wireless tracking and monitoring device are placed between the top plate and the back sheet of the solar panel and are electrically connected to the processor of the wireless tracking and monitoring device affixed to an exposed side of the back sheet at the location inside the junction box interface.

28. The solar panel of claim 26, wherein the one or more sensors and the processor of the wireless tracking and monitoring device are placed between the top plate and the back sheet of the solar panel and are electrically connected to the interface bus of the wireless tracking and monitoring device affixed to an exposed side of the back sheet at the location inside the junction box interface.

29. The solar panel of claim 26, wherein the processed sensor values are stored in the memory and the information stored in the memory are accessible through the wireless communication interface of the wireless tracking and monitoring device.

30. The solar panel of claim 26, wherein the processed sensor values are transmitted through the wireless communication interface of the wireless tracking and monitoring device without being stored in the memory.

31. The solar panel of claim 26, wherein the wireless tracking and monitoring device further comprises one or more sensors configured to measure a solar panel voltage, a solar panel current, a temperature value of the photovoltaic cells or a humidity value of the assembly of photovoltaic cells.

32. The solar panel of claim 31, wherein the one or more sensors of the wireless tracking and monitoring device are electrically connected to the solar panel or one or more photovoltaic cells to measure the solar panel voltage, the solar panel current and the temperature value of the photovoltaic cells.

33. The solar panel of claim 26, wherein the processor comprises an analog-to-digital converter configured to digitize the measured sensor values.

34. The solar panel of claim 26, wherein the processor is powered by a voltage of the solar panel.

35. The solar panel of claim 26, further comprising a battery to supply power to the wireless tracking and monitoring device.

36. The solar panel of claim 26, wherein the antenna is formed as conductive traces embedded between the top plate and the back sheet of the solar panel.

37. The solar panel of claim 26, wherein the antenna is formed as conductive traces on a front side of the top plate of the solar panel or on a back side of the back sheet of the solar panel.

38. The solar panel of claim 26, wherein the wireless tracking and monitoring device comprises a radio frequency identification (RFID) device, the RFID device being a passive RFID device powered by the energy received on the antenna or an active RFID device powered by a voltage of the solar panel or by a battery power.

39. A system to track and monitor a solar panel array, comprising:
an array of solar panels, each solar panel comprising an assembly of interconnected photovoltaic cells and a wireless tracking device placed between a top plate and a back sheet of the solar panel, the wireless tracking device comprising a wireless communication interface and a memory, the solar panel further comprising an antenna formed on or in the solar panel and in electrical communication with the wireless communication interface of the wireless tracking device, wherein the memory of the wireless tracking device is configured to store at least identification and identity information of the solar panel or identification and identity information of one or more of the photovoltaic cells of the solar panel, the information in the memory being accessible through the wireless communication interface of the wireless tracking device;
one or more power inverters connected to the array of solar panels; and
a wireless communication reader configured to communicate with the wireless tracking device in one or more solar panels to retrieve information stored in the memory of the wireless tracking device through wireless communication.

40. The system of claim 39, wherein the wireless tracking device comprises a wireless tracking and monitoring device including the wireless communication interface and the memory, the wireless tracking and monitoring device further comprising:
one or more sensors configured to measure one or more operational parameters of the solar panel or the photovoltaic cells, the one or more sensors generating measured sensor values;
a processor configured to process measured sensor values; and
an interface bus coupled between the processor and the memory and between the processor and the wireless communication interface to provide the processed sensor values to the memory or to the wireless communication interface.
